(19) United States
(12) Patent Application Publication
(10) Pub. No.: US 2026/0333968 A1
(43) Pub. Date: Oct. 22, 2026

(54) LIGHT-EMITTING SUBSTRRATE, BACKLIGHT SOURCE AND DISPLAY DEVICE

(71) Applicants: BOE MLED TECHNOLOGY CO., LTD., Beijing (CN); BOE TECHNOLOGY GROUP CO., LTD., Beijing (CN)

(72) Inventors: Jiaxin LI, Beijing (CN); Donglei LI, Beijing (CN); Kun LU, Beijing (CN); Tonghua YANG, Beijing (CN); Honghao YU, Beijing (CN); Yong LI, Beijing (CN); Dongdong MA, Beijing (CN); Yufan MU, Beijing (CN)

(73) Assignees: BOE MLED TECHNOLOGY CO., LTD., Beijing (CN); BOE TECHNOLOGY GROUP CO., LTD., Beijing (CN)

(21) Appl. No.: 18/994,368

(22) PCT Filed: Oct. 24, 2023
(86) PCT No.: PCT/CN2023/126276

§ 371 Date: Jan. 14, 2025

(51) Int. Cl. H10H 29/34; H10H 29/853; H10H 29/855

(52) U.S. Cl. CPC H10H 29/34; H10H 29/853; H10H 29/855

(57) ABSTRACT

A light-emitting substrate, a backlight source and a display device are provided. The light-emitting substrate includes a substrate and a plurality of light-emitting units located on the substrate. The substrate includes a first region and a second region, the first region includes a center of the substrate, and the second region is located at an edge of the substrate. The plurality of light-emitting units include at least a plurality of first light-emitting units and a plurality of second light-emitting units, the plurality of first light-emitting units are located in the first region, the plurality of second light-emitting units are located in the second region, a distance between at least two adjacent first light-emitting units is greater than a distance between at least two adjacent second light-emitting units or a light intensity of a first light-emitting unit is less than a light intensity of a second light-emitting unit.

### TECHNICAL FIELD

Embodiments of the present disclosure relate to a light-emitting substrate, a backlight source and a display device.

### BACKGROUND

A liquid crystal display device includes a backlight source and a liquid crystal display panel. The backlight source may be a direct-lit backlight source, in order to achieve the purpose of zonal dimming and reducing light leakage. The direct-lit backlight adopts a sub-millimeter light-emitting diode (Mini LED) as a light-emitting element, enabling the excellent characteristics of ultra-thin thickness and ultra-high contrast and vividness of the liquid crystal display device, and thus is favored by more and more consumers.

### SUMMARY

The present disclosure provides a light-emitting substrate, a backlight source and a display device.

Embodiments of the disclosure provide a light emitting structure, including a substrate, comprising at least a first region and a second region, the first region comprising a center of the substrate, and the second region being located at an edge of the substrate; and a plurality of light-emitting units, located on the substrate; wherein the plurality of light-emitting units include at least a plurality of first light-emitting units and a plurality of second light-emitting units, the plurality of first light-emitting units are located in the first region, the plurality of second light-emitting units are located in the second region, a distance between at least two adjacent first light-emitting units is greater than a distance between at least two adjacent second light-emitting units, or a light intensity of a first light-emitting unit is less than a light intensity of a second light-emitting unit.

For example, according to an embodiment of the present disclosure, a ratio of an illuminance at any point in the second region to an illuminance at any point in the first region is in a range from 0.6 to 1.

For example, according to an embodiment of the present disclosure, the second region surrounds the first region, and a minimum distance between an edge of the second region close to the center of the substrate and an edge of a light-emitting region of the light-emitting substrate is not greater than 30 mm.

For example, according to an embodiment of the present disclosure, an edge of the first region is in contact with an edge of the second region, the plurality of first light-emitting units in the first region are equally spaced, and at least some of the plurality of second light-emitting units in the second region are unequally spaced.

For example, according to an embodiment of the present disclosure, the second region comprises at least a first sub-region and a second sub-region, the first sub-region is located between the second sub-region and the first region, and a distance between at least two adjacent second light-emitting units in the second sub-region is less than a distance between at least two adjacent second light-emitting units in the first sub-region.

For example, according to an embodiment of the present disclosure, the first region is in a shape of a quadrangle, the plurality of light-emitting units are arranged in an array in a direction parallel to a first side and a direction parallel to a second side of the quadrangle, the first side and the second side are connected to each other, and a distance between adjacent second light-emitting units gradually decreases in a direction pointing from the center of the substrate to the edge of the substrate and parallel to at least one of the first side and the second side.

For example, according to an embodiment of the present disclosure, further including: a plurality of light transmitting protection structures, which are disposed in a one-to-one correspondence with the plurality of light-emitting units and wrap a portion of the plurality of light-emitting units other than a portion in contact with the substrate, wherein the light transmitting protection structure corresponding to the second light-emitting unit in at least a portion of the second region is provided with an inorganic light emitting material, and the at least a portion of the second region comprises a region that is farthest from the center of the substrate in the second region.

For example, according to an embodiment of the present disclosure, the second region comprises at least a first sub-region and a second sub-region, the first sub-region is located between the second sub-region and the first region, and light transmitting protection structures corresponding to at least some second light-emitting units at least in the second region are provided with the inorganic light emitting material.

For example, according to an embodiment of the present disclosure, a concentration of the inorganic light emitting material disposed in at least one light transmitting protection structure in the second sub-region is greater than a concentration of the inorganic light emitting material disposed in at least one light transmitting protection structure in the first sub-region.

For example, according to an embodiment of the present disclosure, further including: a light conversion layer, located on a side of the plurality of light transmitting protection structures away from the substrate, wherein the plurality of light-emitting units emit blue light, the light conversion layer is configured to convert the blue light emitted by the plurality of light-emitting units to white light, and the inorganic light emitting material is configured to convert the blue light emitted by the plurality of second light-emitting units to white light.

For example, according to an embodiment of the present disclosure, the light conversion layer comprises at least one of a quantum dot material and a fluorescent material.

For example, according to an embodiment of the present disclosure, a light intensity of the first light-emitting unit is less than a light intensity of the second light-emitting unit, the plurality of light-emitting units are arranged in an array, and the plurality of light-emitting units are equally spaced in at least one arrangement direction.

For example, according to an embodiment of the present disclosure, further including: a reflection layer, located on a side of the substrate provided with the plurality of light-emitting units, wherein the reflection layer comprises a plurality of openings, the plurality of openings are disposed in one-to-one correspondence with the plurality of light-emitting units.

For example, according to an embodiment of the present disclosure, a material of the plurality of light transmitting protection structures comprises organic silica gel, and a refractive index of the plurality of light transmitting protection structures is in a range from 1.3 to 1.7 and a transmissivity of the plurality of light transmitting protection structures is greater than 80%.

For example, according to an embodiment of the present disclosure, each light-emitting unit comprises an unpackaged light-emitting diode chip, and a maximum size of the unpackaged light-emitting diode chip in a direction parallel to the substrate is not greater than 500 μm.

The present disclosure provides a backlight source, including the light-emitting substrate according to any items as mentioned above.

The present disclosure provides a display device, including the light-emitting substrate according to any items as mentioned above.

### BRIEF DESCRIPTION OF DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1 is a schematic diagram of a planar structure of a light-emitting substrate according to an embodiment of the present disclosure.

FIG. 2 is a schematic diagram of illuminance distribution of a light-emitting substrate according to an embodiment of the present disclosure.

FIG. 3 and FIG. 4 are light ray diagrams of illuminance distribution of a light-emitting substrate according to an embodiment of the present disclosure.

FIG. 5 is a diagram of different illuminance curves corresponding to different spacings of second light-emitting units in a second region.

FIG. 6 to FIG. 8 are schematic diagrams of a partial cross-sectional structure taken along line AA′ shown in FIG. 1 according to different examples of an embodiment of the present disclosure.

FIG. 9 is a schematic structural diagram of a planar structure of a light-emitting substrate according to another example of an embodiment of the present disclosure.

FIG. 10 is a schematic block diagram of a backlight source according to another embodiment of the present disclosure.

FIG. 11 is a schematic diagram of a partial cross-sectional structure of a display device according to another embodiment of the present disclosure.

### DETAILED DESCRIPTION

In order to make objects, technical details and advantages of the embodiments of the disclosure apparent, the technical solutions of the embodiment will be described in a clearly and fully understandable way in connection with the drawings related to the embodiments of the disclosure. It is obvious that the described embodiments are just a part but not all of the embodiments of the disclosure. Based on the described embodiments herein, those skilled in the art can obtain other embodiment(s), without any inventive work, which should be within the scope of the disclosure.

Unless otherwise specified, the technical terms or scientific terms used in the disclosure shall have normal meanings understood by those skilled in the art. The words “first”, “second” and the like used in the disclosure do not indicate the sequence, the number or the importance but are only used for distinguishing different components. The word “comprise”, “include” or the like only indicates that an element or a component before the word contains elements or components listed after the word and equivalents thereof, not excluding other elements or components. As used in embodiments of the present disclosure, the features “parallel”, “perpendicular”, and “identical” include the features “parallel”, “perpendicular”, and “identical,” etc. in the strict sense, as well as “approximately parallel”, “approximately perpendicular”, and “approximately identical,” etc., which include a certain amount of error, are indicated to be within a range of acceptable deviations for a particular value as determined by a person of ordinary skill in the art, taking into account the measurement and the error associated with the measurement of the particular quantity (e.g., the limitation of the measurement system). For example, “substantially” can mean within one or more standard deviations, or within 10% or 5% of the stated value. Where the quantity of a component is not specifically indicated in the following embodiments of the present disclosure, it is meant that the component may be one or more, or may be understood to be at least one. “At least one” means one or more, and “a plurality of” means at least two.

In studies, the inventors of the present application have found that: at present, some liquid crystal display devices using direct-lit backlight sources to supply backlight have the phenomenon of edge darkening or bluing during a process of displaying images, which affects the user's overall viewing experience. The reasons for the edge darkening or bluing of a display image include, a direct-lit backlight source includes a light-emitting panel and an optical film group on a light emitting side of the light-emitting panel, a plurality of light-emitting diodes are arranged in an array on the light-emitting panel, brightness distribution of each of the light-emitting diodes is a Gaussian function; in general, a backlight brightness provided by the overall light-emitting panel to a center of a display image is greater than a backlight brightness provided by the overall light-emitting panel to the edge region of the display image, and accordingly, the brightness of the edge region of the display image is less than the brightness of the center region, and the edge region will have obvious darkening phenomenon relative to the center region. The darkened edge of the display device affects user's viewing experience, so the difference between the edge brightness and the center brightness is usually an important index for evaluating the display effect of the display device.

For example, in order to improve the brightness at the edge of the display image, a reflective sheet may be attached to the edge of the display image, an edge structural member such as an inner plastic frame may be tilted at a certain angle, or the edge of a film material may be processed so as to improve the reflectivity of the edge of the light-emitting panel in the backlight source. However, the above improvements require additional parts (e.g., the reflective sheet) or special design of structural members, which increases the difficulty in structural assembly and increases the overall product cost.

In studies, the inventors of the present application have also found that: at present, a light converting film for converting blue light to white light, such as a quantum dot (QD) film, in the optical film group suffer from the problem of edge failure. For example, as compared with a light-emitting diode located in the center region of the light-emitting panel, blue light emitted from a light-emitting diode located in the edge region of the light-emitting panel of the backlight source cannot be completely converted to white light after passing through the quantum dot film, i.e., the edge region has a risk of being blue.

Generally, the risk of edge bluing can be resolved by attaching a strip light converting structure to the edge of the light-emitting panel. For example, the blue light emitted by the light-emitting diode at the edge of the light-emitting panel is converted to white light by the strip light converting structure, so that the efficiency of converting the blue light at the edge to white light can be improved. However, this method requires an additional attachment process, which increases the difficulty in the process of assembling the backlight and increases the overall product cost; moreover, since a core material in the strip light converting structure is phosphor, in the process of making the strip light converting structure, concentration of the phosphor and density of particles will affect the efficiency of converting the blue light to white light, and during the actual development process, constant experimentation, testing, and adjustment are required, resulting in a long product development cycle; in addition, as the strip light converting structure is attached to a corresponding area, the risk of peeling off due to aging of the strip light converting structure is increased with the increase in product service time.

Embodiments of the present disclosure provide a light-emitting substrate, a backlight source and a display device. The light-emitting substrate includes a substrate and a plurality of light-emitting units located on the substrate. The substrate includes at least a first region and a second region, the first region includes a center of the substrate, and the second region is located at an edge of the substrate. The plurality of light-emitting units include at least a plurality of first light-emitting units and a plurality of second light-emitting units, the plurality of first light-emitting units are located in the first region, the plurality of second light-emitting units are located in the second region, a distance between at least two adjacent first light-emitting units is greater than a distance between at least two adjacent second light-emitting units or a light intensity of a first light-emitting unit is less than a light intensity of a second light-emitting unit.

In the light-emitting substrate provided in the present disclosure, the distance between adjacent first light-emitting units is set to be greater than the distance between adjacent second light-emitting units, or the light intensity of the first light-emitting unit is set to be less than the light intensity of the second light-emitting unit, which is conducive to reducing the brightness difference between the first region and the second region of the light-emitting substrate, improving the brightness uniformity of the display image when the light-emitting substrate is used for display, and improving product performance. Moreover, it solves the undesirable phenomena such as edge darkening or bluing, reduces the difficulty in product assembly, improves assembly efficiency, and lowers costs.

The light-emitting substrate, the backlight source and the display device provided by the embodiments of the present disclosure will be described below with reference to the accompanying drawings.

FIG. 1 is a schematic diagram of a planar structure of a light-emitting substrate according to an embodiment of the present disclosure. As shown in FIG. 1, the light-emitting substrate includes a substrate 01 and a plurality of light-emitting units 200 located on the substrate 01. The substrate 01 includes at least a first region 110 and a second region 120, the first region 110 includes a center of the substrate 01, and the second region 120 is located at an edge of the substrate 01. The center of the substrate described above refers to a geometric center of a main plane of the substrate parallel to an XY plane shown in FIG. 1.

For example, as shown in FIG. 1, the center of the substrate 01 may be a center of the first region 110, but without being limited thereto, there may be a small distance between the center of the substrate and the center of the first region. For example, the second region 120 may include a region surrounding the first region 110. For example, the second region 120 includes light-emitting units 200 located at the most edge of the substrate 01. For example, the first region 110 may be in a shape of a quadrangle, such as a parallelogram and a rectangle, or a regular shape such as an oval and a circle, or an irregular shape. For example, the second region 120 may be in the shape of a ring. For example, FIG. 1 schematically shows that a boundary that is of the second region 120 and that is close to the center of the substrate 01 is a boundary of the first region 110, and the two boundaries coincide. However, this embodiment is not limited thereto, the boundary that is of the second region 120 and that is close to the center of the substrate 01 does not coincide with the boundary of the first region 110, and the two boundaries may have a certain distance from each other. It can be understood that the boundary of the first region 110 may not overlap with any light-emitting unit 200, and the boundary of the second region 120 may not overlap with any light-emitting unit 200.

As shown in FIG. 1, the plurality of light-emitting units 200 include at least a plurality of first light-emitting units 210 and a plurality of second light-emitting units 220. The plurality of first light-emitting units 210 are located in the first region 110 and the plurality of second light-emitting units 220 are located in the second region 120. For example, a boundary between the first region 110 and the second region 120 may be located between the first light-emitting units 210 and the second light-emitting units 220.

For example, as shown in FIG. 1, different first light-emitting units 210 have the same features, such as a size model, a light intensity distribution, and the like. For example, at least some of the plurality of second light-emitting units 220 have the same features, such as a size, and a light intensity. For example, in one example, the first light-emitting units 210 have the same features as the second light-emitting units 220.

For example, as shown in FIG. 1, a distance between two adjacent first light-emitting units 210 is not equal to a distance between two adjacent second light-emitting units 220. The distance between two adjacent light-emitting units 200 may refer to a distance between centers of two adjacent light-emitting units 200 or a distance between edges that are of the two adjacent light-emitting units 200 and that are close to each other.

For example, FIG. 1 schematically shows that the distance between adjacent first light-emitting units 210 arranged in an X-direction is not equal to the distance between adjacent second light-emitting units 220 arranged in the X-direction in a partial region, and that the distance between adjacent first light-emitting units 210 arranged in a Y-direction is not equal to the distance between adjacent second light-emitting units 220 arranged in the Y-direction in a partial region. However, this embodiment is not limited thereto, the distance between adjacent second light-emitting units 220 in different regions may be set according to the condition of edge brightness. For example, the distance between adjacent second light-emitting units 220 arranged in any direction in the same region of the second region 120 is not equal to the distance between adjacent first light-emitting units 210 arranged in the same direction as the any direction described above. For example, the X-direction and the Y-direction intersect, e.g., an angle between the two may be a range from 80 degrees to 100 degrees, e.g. the two are perpendicular to each other. For example, the X-direction and the Y-direction may be extension directions of the connected two edges of the substrate 01, respectively.

As shown in FIG. 1, in at least one example of this embodiment of the present disclosure, the distance between at least two adjacent first light-emitting units 210 is greater than the distance between at least two adjacent second light-emitting units 220. In at least one example of this embodiment of the present disclosure, a light intensity of the first light-emitting unit 210 is less than a light intensity of the second light-emitting unit 220. For example, the light intensity of the first light-emitting unit 210 in the light-emitting substrate shown in FIG. 1 is equal to the light intensity of the second light-emitting unit 220.

In the light-emitting substrate provided in the present disclosure, the distance between adjacent first light-emitting units is set to be greater than the distance between adjacent second light-emitting units, or the light intensity of the first light-emitting unit is set to be less than the light intensity of the second light-emitting unit, which is conducive to reducing the brightness difference between the first region and the second region of the light-emitting substrate, improving the brightness uniformity of the display image when the light-emitting substrate is used for display, making the display image have an effect more closely approximate to the real visual effect, and improving the product performance.

As compared with the way of setting the light-emitting units in the light-emitting substrate equally spaced, in the light-emitting substrate provided in the present disclosure, the spacing between adjacent second light-emitting units in the second region at the edge of the substrate is set to be less, thus avoiding the step of providing additional parts to improve the edge brightness, reducing the difficulty in product assembly, improving assembly efficiency, and lowering costs.

In some examples, as shown in FIG. 1, the second region 120 surrounds the first region 110, and a minimum distance between an edge of the second region 120 close to the center of the substrate 01 and an edge of a light-emitting region of the light-emitting substrate is not greater than 30 mm. For example, an edge of the second region 120 away from the center of the substrate 01 may be an edge of the light-emitting region of the light-emitting substrate.

For example, the second region 120 is in the shape of a ring, and a ring width of the ring is not greater than 30 mm. The ring width may refer to an average width or a maximum width of the ring-shaped second region 120. For example, the minimum distance between the edge of the second region 120 close to the center of the substrate 01 and the edge of the light-emitting region is not greater than 27 mm. For example, the minimum distance between the edge of the second region 120 close to the center of the substrate 01 and the edge of the light-emitting region is not greater than 25 mm. For example, the minimum distance between the edge of the second region 120 close to the center of the substrate 01 and the edge of the light-emitting region is not greater than 24 mm. For example, the minimum distance between the edge of the second region 120 close to the center of the substrate 01 and the edge of the light-emitting region is not greater than 22 mm. For example, the minimum distance between the edge of the second region 120 and close to the center of the substrate 01 and the edge of the light-emitting region is not greater than 20 mm. For example, the minimum distance between the edge of the second region 120 close to the center of the substrate 01 and the edge of the light-emitting region is not greater than 18 mm. For example, the minimum distance between the edge of the second region 120 close to the center of the substrate 01 and the edge of the light-emitting region is not greater than 15 mm. For example, the minimum distance between the edge of the second region 120 close to the center of the substrate 01 and the edge of the light-emitting region is not greater than 12 mm. For example, the minimum distance between the edge of the second region 120 close to the center of the substrate 01 and the edge of the light-emitting region is not greater than 10 mm. For example, the minimum distance between the edge of the second region 120 close to the center of the substrate 01 and the edge of the light-emitting region is not greater than 8 mm. For example, the minimum distance between the edge of the second region 120 close to the center of the substrate 01 and the edge of the light-emitting region is not greater than 5 mm. For example, the minimum distance between the edge of the second region 120 close to the center of the substrate 01 and the edge of the light-emitting region is not greater than 3 mm. For example, the minimum distance between the edge of the second region 120 close to the center of the substrate 01 and the edge of the light-emitting region is not greater than 1 mm.

For example, as shown in FIG. 1, the second region 120 may have the same or different ring widths at different positions. For example, the second region 120 includes a part that extends in the X-direction and a part that extends in the Y-direction. The width of the part that extends in the X-direction may be a ring width and the width of the part that extends in the Y-direction may also be a ring width. The two parts may have the same or different widths. For example, the width of the part in the second region 120 that extends in the X-direction is less than the width of the part in the second region 120 that extends in the Y-direction. For example, the width of the part of the second region 120 that extends in the X-direction is greater than the width of the part of the second region 120 that extends in the Y-direction.

In some examples, as shown in FIG. 1, each light-emitting unit 200 includes an unpackaged light-emitting diode chip, and a maximum size of the unpackaged light-emitting diode chip in the direction parallel to the substrate 01 is not greater than 500 μm.

For example, as shown in FIG. 1, the light-emitting diode may be a sub-millimeter light-emitting diode (Mini LED) or a micro light-emitting diode (Micro LED).

For example, each light-emitting unit 200 may include a p-electrode, a p-type semiconductor layer, an n-electrode, an n-type semiconductor layer, and a light-emitting layer. Holes and electrons are injected into the n-type semiconductor layer and the p-type semiconductor layer from the n-electrode and the p-electrode, respectively, and recombine within the light-emitting layer and manifest the release of energy in the form of photons, where the emission wavelength is dependent on a forbidden bandwidth of a light emitting material.

For example, as shown in FIG. 1, a maximum size of the light-emitting unit 200 in a direction parallel to the substrate 01 is not greater than 300 μm. For example, the maximum size of the light-emitting unit 200 in the direction parallel to the substrate 01 is not greater than 250 μm. For example, the maximum size of the light-emitting unit 200 in the direction parallel to the substrate 01 is not greater than 220 μm. For example, the maximum size of the light-emitting unit 200 in the direction parallel to the substrate 01 is not greater than 200 μm. For example, the maximum size of the light-emitting unit 200 in the direction parallel to the substrate 01 is not greater than 150 μm.

For example, as shown in FIG. 1, the outline shape of an orthographic projection of the light-emitting unit 200 on the substrate 01 may be in the shape of a rectangle, and the maximum size of the light-emitting unit 200 in the direction parallel to the substrate 01 may be a length of a diagonal of the light-emitting unit 200. Of course, this embodiment of the present disclosure is not limited thereto. For example, the outline shape of the orthographic projection of the light-emitting unit 200 on the substrate 01 may be circular, and the maximum size of the light-emitting unit 200 in the direction parallel to the substrate 01 may be a diameter of the light-emitting unit 200. For example, the outline shape of the orthographic projection of the light-emitting unit 200 on the substrate 01 may be ellipse, and the maximum size of the light-emitting unit 200 in the direction parallel to the substrate 01 may be a length of a major axis of the light-emitting unit 200. However, this embodiment is not limited thereto, a side length of the planar shape of the light-emitting unit 200 is also not greater than 500 μm.

In some examples, as shown in FIG. 1, an edge of the first region 110 is in contact with an edge of the second region 120, the plurality of first light-emitting units 210 in the first region 110 are equally spaced, and at least some of the plurality of second light-emitting units 220 in the second region 120 are unequally spaced. For example, the second region 120 may include a plurality of regions, and the second light-emitting units 220 in at least one region are unequally spaced.

For example, as shown in FIG. 1, a distance between any adjacent first light-emitting units 210 of the plurality of first light-emitting units 210 that are arranged in the X-direction is D1, and a distance between adjacent second light-emitting units 220 of a first part of the plurality of second light-emitting units 220 that are arranged in the X-direction is D2, where D2 is less than D1. For example, D2 may be a larger spacing among spacings of the second light-emitting units 220 that are unequally spaced. For example, a distance between adjacent second light-emitting units 220 of a second part of the plurality of second light-emitting units 220 that are arranged in the X-direction is D3, where D3 is less than D2. The first part of the second light-emitting units 220 and the second part of the second light-emitting units 220 are unequally spaced.

For example, as shown in FIG. 1, a distance between a first light-emitting unit 210 and a second light-emitting unit 220 that are adjacent to each other may be equal to the distance between adjacent first light-emitting units 210. However, this embodiment is not limited thereto, the distance between the first light-emitting unit 210 and the second light-emitting unit 220 that are adjacent to each other may also be equal to the distance between two adjacent second light-emitting units 220.

In some examples, as shown in FIG. 1, the second region 120 includes at least a first sub-region 121 and a second sub-region 122, the first sub-region 121 is located between the second sub-region 122 and the first region 110, and a distance between at least two adjacent second light-emitting units 220 in the second sub-region 122 is less than a distance between at least two adjacent second light-emitting units 220 in the first sub-region 121.

As compared with the case that the light-emitting units at various positions of the light-emitting substrate are uniformly arranged, in the light-emitting substrate provided in the present disclosure, the distances between adjacent second light-emitting units in different regions in the second region are set to be different, which is conducive to greatly reducing the difference between the edge brightness and the center brightness and improving the image uniformity, for example, image screen uniformity may be improved by more than 10%.

For example, as shown in FIG. 1, an edge of the first sub-region 121 close to the center of the substrate 01 is the edge of the first region 110, and an edge of the first sub-region 121 away from the center of the substrate 01 is an edge of the second sub-region 122. For example, the first sub-region 121 surrounds the first region 110 and the second sub-region 122 surrounds the first sub-region 121.

For example, as shown in FIG. 1, in a region of the second region 120 that is located on at least one side of the first region 110 in the X-direction, a distance between adjacent second light-emitting units 220 arranged in the X-direction in the first sub-region 121 is D2, and a distance between adjacent second light-emitting units 220 arranged in the X-direction in the second sub-region 122 is D3, where D3 is less than D2. For example, a distance between two second light-emitting units 220 located on two sides of a boundary between the first sub-region 121 and the second sub-region 122 may be D2 or D3.

For example, FIG. 1 schematically shows that the distance between adjacent second light-emitting units arranged in the X-direction in a partial region of the first sub-region is greater than the distance between adjacent second light-emitting units arranged in the X-direction in a partial region of the second sub-region. However, this embodiment is not limited thereto, the distance between adjacent second light-emitting units in the first sub-region and in the second sub-region may be set according to conditions of the edge brightness.

In some examples, as shown in FIG. 1, the first region 110 is in a shape of a quadrangle, the plurality of light-emitting units 200 are arranged in an array in a direction parallel to a first side 111 and a direction parallel to a second side 112 of the quadrangle, the first side and the second side are connected to each other, and a distance between adjacent second light-emitting units 220 gradually decreases in a direction pointing from the center of the substrate 01 to the edge of the substrate and parallel to at least one of the first side 111 and the second side 112. For example, as shown in FIG. 1, the number of the second light-emitting units 220 located on a side of the first region 110 in the X-direction are arranged in the X-direction in the second region 120 is four, and a distance D4 between two second light-emitting units 220 located on both sides of the boundary between the first sub-region 121 and the second sub-region 122 is less than D2 and greater than D3.

For example, as shown in FIG. 1, the first side 111 may be a side extending in the X-direction and the second side 112 may be a side extending in the Y-direction. However, this embodiment is limited thereto, the first side 111 and the second side 112 may be interchangeable. For example, the first region 110 may be in the shape of a rectangle with the first side 111 and the second side 112 perpendicular to each other. For example, the plurality of light-emitting units 200 are arranged in an array in the X-direction and the Y-direction.

For example, as shown in FIG. 1, in the second region 120 which is located on at least one side of the first region 110 in the X-direction, the distance between adjacent second light-emitting units 220 gradually decreases in a direction pointing from the center of the substrate 01 to the edge of the substrate 01 and parallel to the X-direction. For example, in the second region 120 which is located on at least one side of the first region 110 in the Y-direction, the distance between adjacent second light-emitting units 220 gradually decreases in a direction pointing from the center of the substrate 01 to the edge and parallel to the Y-direction.

For example, as shown in FIG. 1, the number of second light-emitting units 220 distributed in a specific area in the first sub-region 121 is less than the number of second light-emitting units 220 distributed in a specific area in the second sub-region 122, and the number of first light-emitting units 210 distributed in a specific area in the first region 110 is less than the number of second light-emitting units 220 distributed in a specific area in the first sub-region 121. The specific area may refer to an area of a square with a side length of a specific value, such as a square with a side length of 1 cm, or a square with a side length of 2 cm. Alternatively, the specific area may refer to a unit area.

For example, as shown in FIG. 1, the outer contour of the second region 120 may be a rectangle, and distribution density of the second light-emitting units 220 in four edge regions of the rectangle may be greater than distribution density of the second light-emitting units 220 in the other regions in the second region 120. For example, edges of the corner regions may be in contact with the edge of the first region 110, or the edges of the corner regions may have a certain distance from the edge of the first region 110.

For example, in some examples, the light-emitting substrate includes a plurality of dimmable sectional areas (not shown), such as dynamic dimmable sectional areas (Local Dimming). For example, the light-emitting substrate further includes a driver chip (not shown) electrically connected to the plurality of light-emitting units 200, the driver chip is configured to control the brightness of light-emitting units 200 in the at least one dimmable sectional area. For example, each dimmable sectional area is provided with a plurality of light-emitting units 200. For example, a number of first light-emitting units 210 included in the dimmable sectional area located in the first region 110 is less than a number of second light-emitting units 220 included in the dimmable sectional area located in the second region 120. For example, the dimmable sectional area in the first region 110 includes four first light-emitting units 210, and the dimmable sectional area in the second region 120 may include six or more second light-emitting units 220. For example, the dimmable sectional area in the first region 110 is a first dimmable sectional area, the dimmable sectional area in the second region 120 is a second dimmable sectional area, and the first light-emitting units 210 in the at least one first dimmable sectional area may be connected in the same way as the second light-emitting units 220 in the at least one second dimmable sectional area. However, this embodiment of the present disclosure is not limited thereto, and the two connection manners may be different. For example, the first light-emitting units 210 located in the at least one first dimmable sectional area are connected in series, and the second light-emitting units 220 located in the at least one second dimmable sectional area may be connected in series sequentially, or they may be divided into a plurality of groups, with the second light-emitting units 220 of each group connected in series and the second light-emitting units 220 of different groups connected in parallel. For example, a number of the first light-emitting units disposed in different first dimmable sectional areas is the same, and the electrical connections are also the same. For example, a number of the second light-emitting units disposed in different second dimmable sectional areas is the same, and the electrical connections are also the same. For example, in other examples, a boundary position of the first region 110 and the second region 120 passes through at least one dimmable sectional area, then the same dimmable sectional area includes a part of the first region 110 and a part of the second region 120, e.g., the same dimmable sectional area includes first light-emitting units 210 located in the first region 110 and second light-emitting units 220 located in the second region 120.

For example, in some examples, the shape of an orthographic projection of a light-emitting unit 200 on the substrate 01 may be rectangular, and the light-emitting area of the first light-emitting units 210 in the at least one first dimmable sectional area may be less than the light-emitting area of the second light-emitting units 220 in the at least one second dimmable sectional area. For example, a light exit angle of the first light-emitting unit 210 in the at least one first dimmable sectional area may be less than a light exit angle of the second light-emitting unit 220 in the at least one second dimmable sectional area. For example, the light-emitting unit 200 may be an unpackaged light-emitting diode chip, and the unpackaged light-emitting diode chip may be considered as a Lambertian emitter. After the light-emitting diode chip is packaged, light with a light exit angle in a range from +α_{1/2} to −α_{1/2} can be emitted, but light with a light exit angle in a range other than +α_{1/2} to −α_{1/2} basically cannot be emitted due to the total reflection. For example, the brightness of the first light-emitting unit 210 in the at least one first dimmable sectional area is less than the brightness of the second light-emitting unit 220 in the at least one second dimmable sectional area. For example, the above setting may be realized by using light-emitting units of different size models, and may also be realized by providing different current signals (including amplitude magnitude of the current and duration of active level of current) to different light-emitting units by designing the drive circuit.

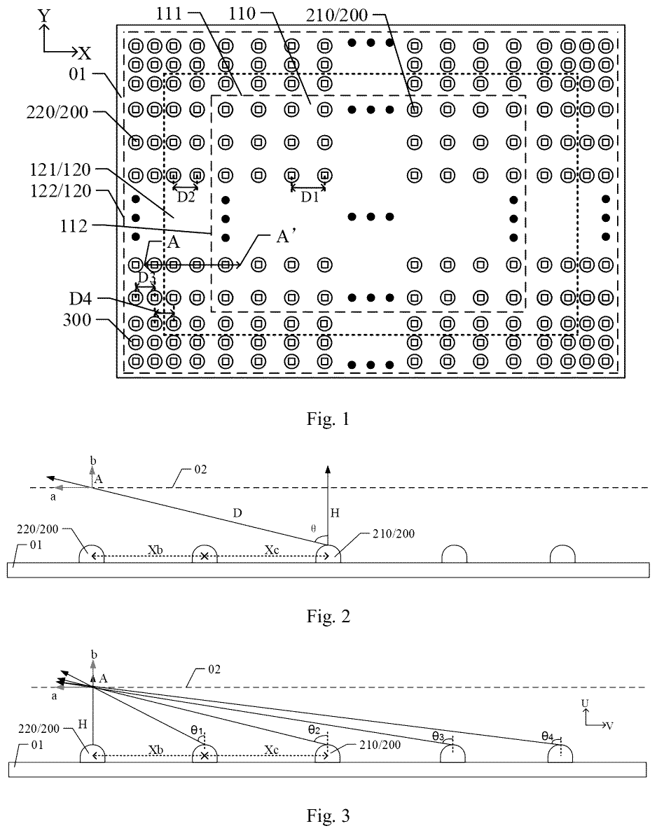

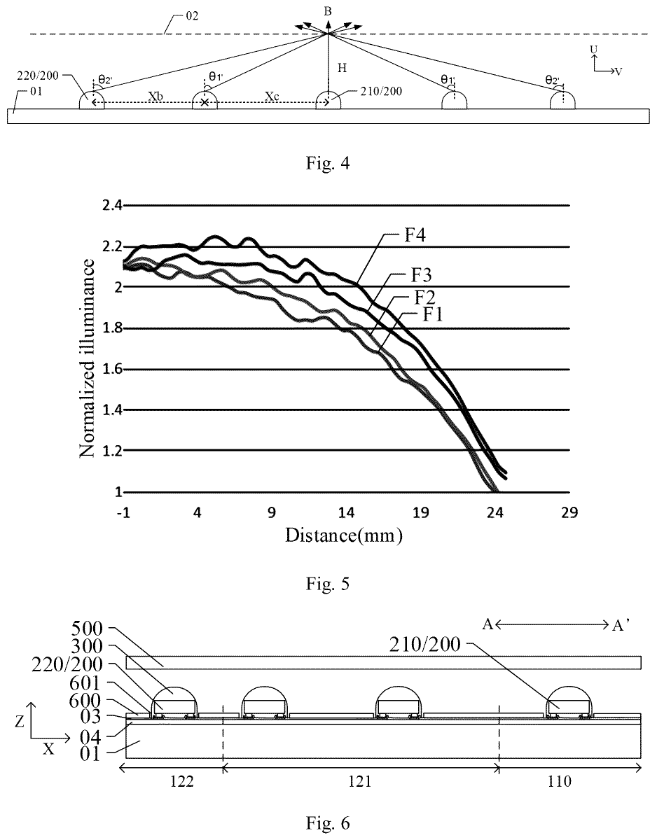

FIG. 2 is a schematic diagram of illuminance distribution of a light-emitting substrate according to an embodiment of the present disclosure. FIG. 3 and FIG. 4 are light ray diagrams of illuminance distribution of a light-emitting substrate according to an embodiment of the present disclosure.

For example, FIG. 2 schematically shows five light-emitting units 200 arranged in a direction in the light-emitting substrate. A third light-emitting unit 200 is regarded as a light-emitting unit 200 located at the center of the light-emitting substrate, and a first light-emitting unit 200 and a fifth light-emitting unit 200 are regarded as light-emitting units 200 located at the edge of the light-emitting substrate. The light emitting side of the light-emitting unit 200 is provided with an optical film material, and a surface of the optical film material closest to the light-emitting unit 200 may be a surface 02 shown in FIG. 2.

For example, after the light emitted from the light-emitting unit 200 is refracted and scattered via the optical film material, brightness distribution of the light-emitting unit 200 may be converted to illuminance distribution of the backlight source. If measured with an illuminometer, generally, the closer the illuminometer is to the light-emitting unit 200, the greater the illuminance value will be; conversely, the less it will be. Illuminance is a physical quantity that indicates the degree to which an object is illuminated. The illuminance is related to positions of the light-emitting unit 200 and the illuminated surface of the optical film material in space, and the illuminance is proportional to the light intensity of the light-emitting unit 200 and the cosine of incident angle of the light, and inversely proportional to the square of a distance from the light-emitting unit 200 to the illuminated surface of the optical film material.

For example, as shown in FIG. 2, the light intensity of the light emitted from each light-emitting unit 200 is I. The light intensity of the light emitted from the light-emitting unit 200 located in the center may be decomposed into a horizontal component a and a vertical component b after acting on a point A. The horizontal component a does not have an effect on the illuminance in a perpendicular direction of the point A, and a distance between the light-emitting unit 200 located in the center and the point A is D, and the illuminance at the point A is E(A)=(I*cos θ)/D2. A distance between the light-emitting unit 200 and the illuminated surface 02 of the optical film material is H, i.e., the optical distance (OD), the H satisfies H=D*cos θ, and the illuminance at the point A is E(A)=(I*cos³θ)/H². The light-emitting unit 200 shown in FIG. 2 is a light-emitting unit 200 wrapped by a light transmitting protection structure 300 (will be described subsequently), and the distance H may be a minimum distance between a surface of the light transmitting protection structure 300 away from the substrate 01 and the surface 02.

With reference to FIG. 3 and FIG. 4 in which the light-emitting substrate includes five light-emitting units 200 arranged in a V-direction is taken as an example, the illuminance at the edge E(L) and the illuminance at the center E(C) are calculated respectively, e.g., the illuminance at the edge E(L) may be the illuminance at a point A directly above the second light-emitting unit 220 at the most edge, and the illuminance at the center E(C) may be the illuminance at a point B directly above the first light-emitting unit 210 at the center. For example, the light intensity of the light emitted from each light-emitting unit 200 is I, i.e., it is assumed that all light-emitting units 200 have the same brightness at the moment that an all-white image is illuminated. For example, a U-direction is perpendicular to a main plane of the substrate 01 and the V-direction is parallel to the main plane of the substrate 01.

For example, as shown in FIG. 3, a distance between adjacent light-emitting units 200 (e.g., the first light-emitting units 210) located in a center region, such as the first region 110, may be Xc; a distance between adjacent light-emitting units 200 (e.g., the second light-emitting units 220) located in an edge region, such as the second region 120, may be Xb; an angle between a light ray of the second light-emitting unit 200 that is emitted to the point A and the U-direction is θ₁; an angle between a light ray of the third light-emitting unit 200 that is emitted to the point A and the U-direction is θ₂, an angle between a light ray of a fourth light-emitting unit 200 that is emitted to the point A and the U-direction is θ₃; and an angle between a light ray of the fifth light-emitting unit 200 that is emitted to the point A and the U-direction is θ₄. The illuminance E(L) satisfies relation equation (1):

E(L)=[I*(1+cos³θ₁+cos³θ₂+cos³θ₃+cos³θ₄)]/H².

For example, Xc and Xb are substituted into E(L) to obtain relation equation (2):

E(L)={I*[1+H³/(Xb²+H²)^{3/2}+H³/((Xb+Xc)²+H²)^{3/2}+H³/((Xb+2*Xc)²+H²)^{3/2}+H³((2*Xb+2*Xc)²+H²)^{3/2}]}/H².

For example, as shown in FIG. 4, angles between light rays emitted from the first light-emitting unit 200 and the fifth light-emitting unit 200 to the point B and the U-direction are both θ₁′, and angles between light rays emitted from the second light-emitting unit 200 and the third light-emitting unit 200 to the point B and the U-direction are both θ₂′ The illuminance E(C) satisfies relation equation (3):

E(C)=[I*(1+2*cos³θ₁′+2*cos³θ₂′)]/H².

For example, Xc and Xb are substituted into E(L) to obtain relation equation (4):

E(C)={I*[1+2*H³/(Xc²+H²)^{3/2}+2*H³/((Xb+Xc)²+H²)^{3/2}]}/H².

For example, as shown in FIG. 3 and FIG. 4, in order to reduce the illuminance difference between the center region and edge region, the illuminance E(L) and the illuminance E(C) satisfy relation equation (5):

E(L)≈E(C).

The closer the illuminance values on both sides of the symbol of approximate equal are, the closer the display effect of the center region of the light-emitting substrate is to the display effect of the edge region.

The relation equations (2) and (4) are substituted into the relation equation (5) to obtain relation equation (6):

{I*[1+H³/(Xb²+H²)^{3/2}+H³/((Xb+Xc)²+H²)^{3/2}+H³/((Xb+2*Xc)²+H²)^{3/2}+H³/(2*Xb+2*Xc)²+H²)^{3/2}]}/H²≈{I*[1+2*H³/(Xc²+H²)^{3/2}+2*H³/(Xb+Xc)²+H²)^{3/2}]}/H².

The relation equation (6) is simplified to obtain relation equation (7):

1/(Xb²+H²)^{3/2}+1/[(Xb+2*Xc)²+H²]^{3/2}+1/[(2*Xb+2*Xc)²+H²]^{3/2}≈2 /(Xc²+H²)^{3/2}+1/[(Xb+Xc)²+H²]^{3/2}.

For example, as shown in FIG. 3 and FIG. 4, the value of a formula on the left of the symbol of approximate equal in the relation equation (7) is denoted as L0, and the value of a formula on the right of the symbol of approximate equal is denoted as C0. Xc is 5 mm, H is 2 mm, and Xb is selected as 5 mm, 4.5 mm, 4.3 mm, 4 mm, and 3.75 mm, respectively, and the values of L0 are obtained as 0.0068, 0.0088, 0.0099, 0.0117, and 0.0136, respectively, and the values of C0 are obtained as 0.0137, 0.0139, 0.0140, 0.0141, and 0.0142, respectively. Thus, it can be seen that L0/C0 is equal to 49.6%, 63.3%, 70.7%, 83%, and 95.8%, respectively. In a case where the distance between adjacent light-emitting units 200 in the edge region is equal to the distance between adjacent light-emitting units 200 in the center region, a ratio of the illuminance in the edge region to the illuminance in the center region is about 50%, which is a large difference. By setting the distance between adjacent light-emitting units 200 in the edge region less than the distance between adjacent light-emitting units 200 in the center region, so that the difference between the illuminance in the edge region and the illuminance in the center region may be decreased. For example, by adjusting the distance between adjacent light-emitting units 200 in the edge region, the ratio of illuminances of the two regions may be adjusted to about 96%, thus improving the uniformity of the light-emitting substrate greatly.

FIG. 5 is a diagram of different illuminance curves corresponding to different spacings of second light-emitting units in a second region.

For example, as shown in FIG. 5, optical simulation software may be used to simulate the illuminance enhancement effect of the second light-emitting units 220 in the second region 120 at different spacings. In a simulation diagram shown in FIG. 5, the abscissa indicates a horizontal distance between an illuminance sampling point and the center of the light-emitting substrate, and the ordinate indicates a normalized illuminance with the illuminance normalized to 1 at an edge illuminance sampling point in a curve F1 (equally spaced). For example, the simulation curve shown in FIG. 5 illustrates the change in illuminance in a direction from the edge of the light-emitting substrate pointing to the center in an interval of 24 mm in length.

For example, in the case that the light-emitting substrate corresponding to the simulation curve shown in FIG. 5 includes ten light-emitting units 200 arranged in the V-direction shown in FIG. 3 and FIG. 4, F1 indicates a curve of illuminance, varying with the distance, of the light-emitting substrate in which the distance between adjacent first light-emitting units 210 in the first region 110 is 1 mm, and the distance between adjacent second light-emitting units 220 in the second region 120 is also 1 mm; F2 indicates a curve of illuminance, varying with the distance, of the light-emitting substrate in which the distance between adjacent first light-emitting units 210 in the first region 110 is 1 mm, and the spacings of a plurality of second light-emitting units 220 in the second region 120 are 0.98 mm, 0.98 mm, 0.98 mm, 0.93 mm, and 0.93 mm sequentially; F3 indicates a curve of illuminance, varying with the distance, of the light-emitting substrate in which the distance between adjacent first light-emitting units 210 in the first region 110 is 1 mm, and the spacings of the second light-emitting units 220 in the second region 120 are 0.93 mm, 0.93 mm, 0.93 mm, 0.87 mm, and 0.87 mm sequentially; F4 indicates a curve of illuminance, varying with the distance, of the light-emitting substrate in which the distance between adjacent first light-emitting units 210 in the first region 110 is 1 mm, and the spacings of the second light-emitting units 220 in the second region 120 are 0.87 mm, 0.87 mm, 0.87 mm, 0.65 mm, and 0.65 mm sequentially. The curve F1 indicates that the light-emitting units 200 in the light-emitting substrate are uniformly arranged, for example, the light-emitting units 200 are equally spaced. The curves F2 to F4 indicate that the spacing of the adjacent first light-emitting units 210 in the light-emitting substrate is greater than the spacing of the adjacent second light-emitting units 220, for example, the light-emitting units 200 on the light-emitting substrate unequally spaced.

For example, as shown in FIG. 5, the ratio of the edge illuminance to the center illuminance in the F1 curve is 0.481; the ratio of the edge illuminance to the center illuminance in the F2 curve is 0.483; the ratio of the edge illuminance to the center illuminance in the curve F3 is 0.533, and the edge uniformity of the light-emitting substrate corresponding to the curve F3 is increased by 11% relative to the light-emitting substrate corresponding to the curve F1; the ratio of the edge illuminance to the center illuminance in the curve F4 is 0.548, and the edge uniformity of the light-emitting substrate corresponding to the curve F4 is increased by 14% relative to the light-emitting substrate corresponding to the curve F1. It can be seen that, with respect to the light-emitting substrate in which the light-emitting units equally spaced, the present disclosure provides a light-emitting substrate in which the spacing of the second light-emitting units 220 in the second region 120 is less than the spacing of the first light-emitting units 210 in the first region 110, and the second light-emitting units 220 in the second region 120 is unequally spaced, which is conducive to greatly increasing the edge luminance, e.g., the edge uniformity of the light-emitting substrate may be increased by more than 10%.

Changing the spacing of the light-emitting units is taken as an example for logical projections corresponding to the above relation equations (1) to (7) provided in the present disclosure, where the second light-emitting units in the second region are arranged unequally spaced, which can significantly improve uniformity of the display image when the light-emitting substrate is applied to the display device. Of course, this embodiment of the present disclosure is not limited thereto. For the above relation equations (1) to (6), Xb and Xc may be set to be equal or both may be respectively set to a certain determined value, and the light intensity I_{L} in the illuminance E(L) is not equal to the light intensity I_{C} in the illuminance E(C), for example, the light intensity of the first light-emitting unit is different from the light intensity of the second light-emitting unit. After I_{C} is determined, I_{L} can be obtained by making the values on both sides of the symbol of approximately equal approach each other.

By means of the above relation equations (1) to (6), the light intensity of the second light-emitting unit can be adaptively adjusted to be greater than the light intensity of the first light-emitting unit, or the distance between adjacent second light-emitting units is less than the distance between adjacent first light-emitting units in order to improve the edge illuminance of the light-emitting substrate, thus improving the display uniformity.

In some examples, as shown in FIG. 1, a ratio of an illuminance of any point in the second region 120 to an illuminance of any point in the first region 110 is in a range from 0.6 to 1. The above-mentioned illuminance at any point refers to the illuminance at any point of all the light-emitting units 200 illuminated on the surface 02 shown in FIG. 3 and FIG. 4, for example, the illuminance at any point in the second region 120 may be the illuminance at the point A, and the illuminance at any point in the first region 110 may be the illuminance at the point B.

In the light-emitting substrate provided in the present disclosure, the light intensity of the first light-emitting unit and the light intensity of the second light-emitting unit may be set according to the above relation equations (1) to (6) to reduce the difference in the illuminance or luminance between the first region and the second region, or the spacing between the first light-emitting units and the spacing between adjacent second light-emitting units may be adjusted to reduce the difference in the illuminance or brightness between the first region and the second region, so as to improve the brightness uniformity of the display image. For example, all light-emitting substrates in which the spacing of the first light-emitting units and the spacing of the second light-emitting units satisfy the above relation equations (1) to (6) fall in the scope of protection of the present application.

For example, as shown in FIG. 1, the ratio of the illuminance at any point in the second region 120 to the illuminance at any point in the first region 110 is in a range from 0.7 to 0.8. For example, the ratio of the illuminance at any point in the second region 120 to the illuminance at any point in the first region 110 is in a range from 0.75 to 0.9. For example, the ratio of the illuminance at any point in the second region 120 to the illuminance at any point in the first region 110 is in a range from 0.65 to 0.95. For example, the ratio of the illuminance at any point in the second region 120 to the illuminance at any point in the first region 110 is in a range from 0.78 to 0.99. For example, the ratio of the illuminance at any point in the second region 120 to the illuminance at any point in the first region 110 is in a range from 0.86 to 0.97. For example, the ratio of the illuminance at any point in the second region 120 to the illuminance at any point in the first region 110 is in a range from 0.82 to 0.92. For example, the ratio of the illuminance at any point in the second region 120 to the illuminance at any point in the first region 110 is in a range from 0.68 to 0.91. For example, the ratio of the illuminance at any point in the second region 120 to the illuminance at any point in the first region 110 is in a range from 0.66 to 0.88. For example, the ratio of the illuminance at any point in the second region 120 to the illuminance at any point in the first region 110 is in a range from 0.76 to 0.89.

FIG. 6 is a schematic diagram of a partial cross-sectional structure taken along line AA′ shown in FIG. 1 according to an example of an embodiment of the present disclosure.

In some examples, as shown in FIG. 6, the light-emitting substrate further includes a reflection layer 600 on a side of the substrate 01 where a plurality of light-emitting units 200 are disposed. The reflection layer 600 includes a plurality of openings 601, the plurality of openings 601 are disposed in one-to-one correspondence with the plurality of light-emitting units 200. For example, the light-emitting substrate may be of a direct-lit structure. For example, the reflection layer 600 is configured to change a propagation direction of light ray incident on a surface away from the substrate 01 to enable the light ray to be emitted to the light conversion layer 500 (described subsequently). For example, the reflection layer 600 may be located in a region, on the substrate 01, between adjacent light-emitting units 200 and between the body of the light-emitting unit 200 and the substrate 01.

The light-emitting substrate provided in the present disclosure can directly solve the problem of poor display at the edge of an image with low cost and high efficiency, and can be used in the direct-lit backlight to greatly improve the display image uniformity and improve the product performance.

For example, as shown in FIG. 6, the material of the reflection layer 600 may include white ink and/or silicone-based white glue.

For example, as shown in FIG. 6, in a direction perpendicular to the substrate 01, there is no overlap between the light-emitting unit 200 and the reflection layer 600.

For example, as shown in FIG. 6, a buffer layer 04 (Buffer) is disposed on the substrate 01. For example, a pad is disposed on a side of the buffer layer 04 away from the substrate 01, the light-emitting unit 200 includes a pin and a light-emitting body, and the pin of the light-emitting unit 200 is electrically connected to the pad. For example, a passivation layer 03 (PVX) is also disposed on the side of the buffer layer 04 away from the substrate 01. For example, a material of the passivation layer 03 includes an insulating material, and the passivation layer 03 includes an opening 601 at least exposing the pad t to enable the pins of the light emitting units 200 to be electrically connected to the pads exposed by the passivation layer 03. The light-emitting unit 200 may be an upright light-emitting diode or an inverted light-emitting diode. FIG. 6 schematically shows only the buffer layer 04 and the passivation layer 03 between the light-emitting units 200 and the substrate 01. However, this embodiment is not limited thereto, other film layers may be included between the light-emitting units 200 and the substrate 01, for example, other film layers may be included between the buffer layer 04 and the passivation layer 03.

In some examples, as shown in FIG. 6, the light-emitting substrate further includes a plurality of light transmitting protection structures 300 that are disposed in one-to-one correspondence with the plurality of light-emitting units 200 and wrap a portion of the plurality of light-emitting units 200, other than a portion in contact with the substrate 01. For example, FIG. 6 schematically shows that in the direction perpendicular to the substrate 01, there is no overlap between the light transmitting protection structures 300 and the reflection layer 600. However, this embodiment is not limited thereto, an edge of the light transmitting protection structure 300 may cover an edge of the reflection layer 600. For example, a plurality of light transmitting protection structures 300 are spaced apart.

For example, as shown in FIG. 6, the light transmitting protection structure 300 may wrap the portion of the light-emitting unit 200 other than a surface where the pin and the pad are connected electrically, to package and protect the unpackaged light-emitting unit 200. For example, the light transmitting protection structure 300 is in direct contact with the light-emitting unit 200, e.g., the surface of the light-emitting unit 200 away from the substrate 01 and the side surface of the light-emitting unit 200 are in direct contact with the light transmitting protection structure 300. For example, there may be no gap between the light transmitting protection structure 300 and the light-emitting unit 200 to avoid the reflection of light between the light-emitting unit 200 and the light transmitting protection structure 300.

In some examples, as shown in FIG. 6, a material of the plurality of light transmitting protection structures 300 includes organic silica gel, and a refractive index of the plurality of light transmitting protection structures 300 is in a range from 1.3 to 1.7 and a transmissivity of the plurality of light transmitting protection structures 300 is greater than 80%. For example, the refractive index of the light transmitting protection structure 300 is in a range from 1.47-1.53. For example, the transmissivity of the light transmitting protection structure 300 is greater than 90%. For example, the transmissivity of the light transmitting protection structure 300 is greater than 92%. For example, the transmissivity of the light transmitting protection structure 300 is greater than 93%. For example, the transmissivity of the light transmitting protection structure 300 is greater than 94%. For example, the transmissivity of the light transmitting protection structure 300 is greater than 95%. For example, the transmissivity of the light transmitting protection structure 300 is greater than 96%. For example, the transmissivity of the light transmitting protection structure 300 is greater than 97%.

For example, as shown in FIG. 6, the material of the light transmitting protection structure 300 may be transparent silicone. For example, the light emitted from the light-emitting unit 200 is refracted by the light transmitting protection structure 300 and then emitted, and the shape of the light transmitting protection structure 300 may determine a secondary pattern of exiting light rays from the light-emitting unit 200. In the light-emitting substrate provided in the present disclosure, the light transmitting protection structure covering the light-emitting unit may be used as a lens to optimize the light exit angle of the light-emitting unit. Because the organic silica gel has a certain refractive index, e.g., a refractive index greater than the refractive index of the air, the light emitted from the light-emitting unit is refracted when it is emitted from the organic silica gel to the air or other media, and the secondary pattern of the light emitted from the light-emitting unit is changed when the light is emitted from the organic silica gel.

In some examples, as shown in FIG. 6, the light-emitting substrate further includes a light conversion layer 500 located on a side of the plurality of light transmitting protection structures 300 away from the substrate 01. The plurality of light-emitting units 200 emit blue light, and the light conversion layer 500 is configured to convert the blue light emitted by the plurality of light-emitting units 200 to white light.

For example, as shown in FIG. 6, an emission wavelength of the light-emitting units 200 emit light is in a range from 430 nanometers to 480 nanometers. For example, the light-emitting unit 200 includes a blue light-emitting chip to emit blue light. For example, an emission wavelength of the light-emitting unit 200 may be in a range from 440 nanometers to 460 nanometers, or from 450 nanometers to 470 nanometers.

In some examples, as shown in FIG. 6, the light conversion layer 500 includes at least one of a quantum dot material and a fluorescent material.

For example, as shown in FIG. 6, the light conversion layer 500 may convert light from the light-emitting unit 200 from one color to another. For example, when the light-emitting unit 200 emits blue light, the light conversion layer 500 may include a phosphor layer that converts the blue light to white light. For example, the phosphor layer includes quantum dots that convert the blue light to red light and green light. For example, Quantum Dot (QD), also known as nanocrystals, generally have a particle size in the range of 1-20 nm. Because of the quantum confinement of electrons and holes, the continuous energy band structure becomes a discrete energy level structure with molecular characteristics, which can emit light of different color from the excitation light after quantum dot is excited. For example, the fluorescent material may be inorganic particles, organic particles, or organic molecules or a combination thereof. Of course, this embodiment of the present disclosure is not limited thereto. The light conversion layer 500 may further include a part of reflection structure. For example, the part of reflection structure (which may also be referred to as a dichroic structure or a dichroic filtering structure) may reflect all of the red and green light and reflect the blue light partially.

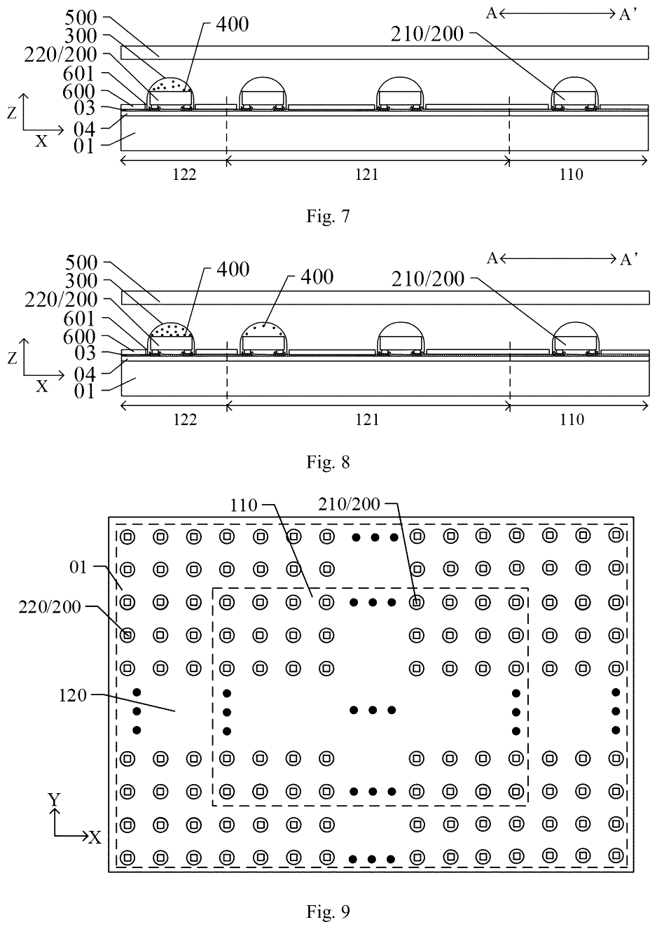

FIG. 7 is a schematic diagram of a partial cross-sectional structure taken along line AA′ shown in FIG. 1 according to another example of an embodiment of the present disclosure. The difference between the light-emitting substrate shown in FIG. 7 and the light-emitting substrate shown in FIG. 6 lies in the arrangement of the light transmitting protection structure 300.

In some examples, as shown in FIG. 7, the light transmitting protection structure 300 corresponding to the second light-emitting unit 220 in at least a portion of the second region 120 is provided with an inorganic light emitting material 400, and the at least a portion of the second region 120 includes a region that is farthest from the center of the substrate 01 in the second region 120. For example, the at least a portion of the second region 120 described above may be a region, at an edge of the light-emitting substrate, in the second region 120.

In some examples, as shown in FIG. 7, the inorganic light emitting material 400 is configured to convert at least part of the blue light emitted by the second light-emitting unit 220 to white light.

As compared with the general light-emitting substrate in which no luminescent material is added into the light transmitting protection structure located at the edge, in the light-emitting substrate provided in the present disclosure, by setting the inorganic light emitting material in the light transmitting protection structure which is located at least in the edge area of the second region, which is conducive to directly curing the light conversion method of converting blue light to white light at the edge of the light-emitting substrate, thereby effectively solving the problem of the light conversion layer such as edge bluing due to failure at the edge of the quantum dot layer to improve the image effect of the light-emitting substrate while greatly lowering the complexity in structure assembly and specification requirements for the light converting film, and lowering costs. In addition, it can also avoid the failure of structure members after long-term use of the product.

In the light-emitting substrate provided in the present disclosure, a solution that the inorganic light emitting material is disposed in the light transmitting protection structure wrapping the second light-emitting unit is applicable to a solution in which all the light-emitting units are arranged uniformly and a solution in which the first light-emitting unit and the second light-emitting unit have the same light intensity.

For example, as shown in FIG. 7, the inorganic light emitting material 400 may be uniformly dispersed in the light transmitting protection structure 300, or aggregated on the light emitting side of the light transmitting protection structure 300.

For example, as shown in FIG. 7, the inorganic light emitting material 400 may include phosphor particles, for example, it may include a fluorescent material. The fluorescent material may be inorganic particles, organic particles, or organic molecules or a combination thereof. Suitable inorganic particles include doped garnets (e.g., YAG:Ce, and (Y,Gd)AG:Ce), aluminates (e.g., Sr2Al14O25:Eu, and BAM:Eu), silicates (e.g., SrBaSiO:Eu), sulphides (e.g., ZnS:Ag, CaS:Eu, and SrGa2S4:Eu), oxysulfides, oxo-nitrides, phosphates, borates, and tungstates (e.g., CaWO4). These materials may be in the form of powder of a conventional inorganic light emitting material 400 or powder of a nanoparticle inorganic light emitting material 400. Another suitable type of inorganic particles refers to a so-called quantum-dot inorganic light emitting material made from semiconductor nanoparticles, including: silicon (Si), germanium (Ge), cadmium sulfide (CdS), cadmium selenide (CdSe), cadmium telluride (CdTe), zinc sulfide (ZnS), zinc selenide (ZnSe), zinc telluride (ZnTe), lead sulfide (PbS), lead selenide (PbSe), Lead telluride (PbTe), indium nitride (InN), indium phosphide (InP), indium arsenide (InAs), aluminum nitride (AlN), aluminum phosphide (AIP), aluminum arsenide (AlAs), gallium nitride (GaN), gallium phosphide (GaP), gallium arsenide (GaAs), and combinations thereof. Generally, the surface of each quantum dot is at least partially covered with organic molecules, thereby preventing agglomeration and improving the compatibility with binders. In some cases, the semiconductor quantum dots may consist of several layers of different materials in a core-shell structure. Suitable organic molecules include fluorescent dyes. A phosphor layer may include a mixture of different types of inorganic light emitting materials 400 in a single layer or multiple layers, and each layer contains one or more inorganic light emitting materials 400. Particles of the inorganic light emitting material 400 in the phosphor layer may have different particle sizes (e.g., diameters) and may be separated.

In some examples, as shown in FIG. 1 and FIG. 7, the second region 120 includes at least a first sub-region 121 and a second sub-region 122, the first sub-region 121 is located between the second sub-region 122 and the first region 110, and at least the light transmitting protection structure 300 corresponding to the second light-emitting unit 220 in at least a portion of the second region 122 is provided with the inorganic light emitting material 400.

For example, as shown in FIG. 1 and FIG. 7, the light transmitting protection structures 300 corresponding to all of the second light-emitting units 220 in the second sub-region 122 are provided with the inorganic light emitting material 400 therein. For example, the second sub-region 122 includes a plurality of circles of second light-emitting units 220 surrounding the first region 110, and only the light transmitting protection structures 300 corresponding to the second light-emitting units 220 in the outermost circle are provided with the inorganic light emitting material 400 therein. However, this embodiment is not limited thereto, the light transmitting protection structures 300 corresponding to the second light-emitting units 220 at the comers of the second sub-region 122 in addition to the second light-emitting units 220 in the outermost circle may also be provided with the inorganic light emitting material 400 therein

FIG. 7 schematically shows that only the light transmitting protection structure 300 corresponding to the second light-emitting unit 220 in the second sub-region 122 is provided with the inorganic light emitting material 400 therein. However, this embodiment is not limited thereto, for example, the light transmitting protection structures 300 corresponding to all of the second light-emitting units 220 in the second sub-region 122 are provided with the inorganic light emitting material 400 therein while the light transmitting protection structures 300 corresponding to at least some second light-emitting units 220, close to the second sub-region 122, in the first sub-region 121 are provided with the inorganic light emitting material 400 therein. For example, the light transmitting protection structures 300 corresponding to all of the second light-emitting units 220 in the second region 120 may be provided with the inorganic light emitting material 400 therein

FIG. 8 is a schematic diagram of a partial cross-sectional structure taken along line AA′ shown in FIG. 1 according to another example of an embodiment of the present disclosure. The difference between the light-emitting substrate shown in FIG. 8 and the light-emitting substrate shown in FIG. 7 lies in the way of providing the inorganic light emitting material 400.

In some examples, as shown in FIG. 8, a concentration of the inorganic light emitting material 400 disposed in at least one light transmitting protection structure 300 in the second sub-region 122 is greater than a concentration of the inorganic light emitting material 400 disposed in at least one light transmitting protection structure 300 in the first sub-region 121. The phenomenon of edge bluing of the light-emitting substrate may be better addressed by adjusting the concentration of the inorganic light emitting material 400 in different sub-regions of the second region 120.

For example, as shown in FIG. 8, distribution density of the inorganic light emitting material 400 disposed in the at least one light transmitting protection structure 300 in the second sub-region 122 is greater than distribution density of the inorganic light emitting material 400 disposed in the at least one light transmitting protection structure 300 in the first sub-region 121.

For example, as shown in FIG. 8, the concentration of the inorganic light emitting material 400 disposed in any one of the light transmitting protection structures 300 in the second sub-region 122 is greater than the concentration of the inorganic light emitting material 400 disposed in any one of the light transmitting protection structures 300 in the first sub-region 121. For example, the light transmitting protection structure 300 in the first sub-region 121 is provided with the inorganic light emitting material 400 only at the light emitting side, and the light transmitting protection structure 300 in the second sub-region 122 is provided with the inorganic light emitting material 400 therein uniformly.

FIG. 9 is a schematic structural diagram of a planar structure of a light-emitting substrate according to another example of an embodiment of the present disclosure; The difference between the light-emitting substrate shown in FIG. 9 and the light-emitting substrate shown in FIG. 1 is that the light intensity of the first light-emitting unit 210 is less than the light intensity of the second light-emitting unit 220, and the light-emitting units 200 are arranged in a different manner. A substrate 01, the position of a first region 110, the position of a second region 120, a reflection layer 600, a light conversion layer 500, a light transmitting protection structure 300, and an inorganic light emitting material 400 in the light transmitting protection structure 300 in the light-emitting substrate shown in FIG. 9 may have the same features as the corresponding structures in the light-emitting substrate shown in FIG. 1, and will not be repeated herein.

In some examples, as shown in FIG. 9, a light intensity of the first light-emitting unit 210 is less than a light intensity of the second light-emitting unit 220, the plurality of light-emitting units 200 are arranged in an array, and the plurality of light-emitting units 200 are equally spaced in at least one arrangement direction.

For example, as shown in FIG. 9, the plurality of light-emitting units 200 are equally spaced in an X-direction and a Y-direction. For example, a distance between adjacent first light-emitting units 210 is equal to a distance between adjacent second light-emitting units 220.

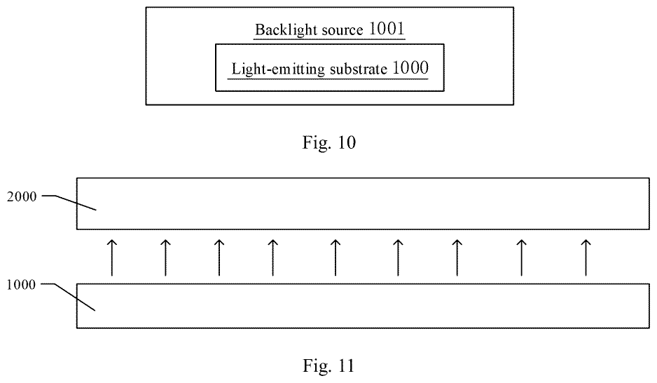

FIG. 10 is a schematic block diagram of a backlight source according to another embodiment of the present disclosure. As shown in FIG. 10, the backlight source 1001 includes a light-emitting substrate 1000 in any of the above examples.

For example, as shown in FIG. 10, the backlight source further includes a light diffusion structure located on the light emitting side of the light-emitting substrate 1000. For example, the light diffusion structure may include at least one light diffusion layer. For example, the light diffusion structure may include a first light diffusion layer and a second light diffusion layer, one of the first light diffusion layer and the second light diffusion layer may be a particulate diffusion plate, and the other of the first light diffusion layer and the second light diffusion layer may be a diffusion film with microstructures on the surface. However, this embodiment is not limited thereto, the light diffusion structure may include more diffusion layers, for example.

For example, the backlight source may further include a diffusion layer, a brightness enhancing film, and the like. For example, the diffusion layer, the brightness enhancing film, and the light conversion layer 500 and other film layers are located on a side of the light diffusion structure away from the light-emitting substrate. For example, the brightness enhancing film may be a prism layer that functions to converge light and improve the brightness of the light emitted at the positive viewing angle.

FIG. 11 is a schematic diagram of a partial cross-sectional structure of a display device according to another embodiment of the present disclosure. As shown in FIG. 11, the display device includes a light-emitting substrate 1000 in any of the above examples. For example, as shown in FIG. 11, the display device may include the backlight source shown in FIG. 10.

For example, as shown in FIG. 11, the display device further includes a display panel 2000 stacked on the light-emitting substrate 1000. For example, the display panel 2000 is located at the light emitting side of the light-emitting substrate 1000, and the light-emitting substrate 1000 is configured to provide back light to the display panel 2000. For example, the display panel 2000 may be a liquid crystal display panel. The liquid crystal display panel may include an array substrate (not shown), an opposing substrate (not shown), and a liquid crystal layer (not shown) located between the array substrate and the opposing substrate.

For example, one side of the array substrate facing toward the opposing substrate may include a plurality of gate lines extending in one direction and a plurality of data lines extending in another direction. The plurality of gate lines and the plurality of data lines intersect to define a plurality of pixel units arranged in an array. The plurality of pixel units may be arranged as a pixel array. Each pixel unit may include a pixel electrode and a thin-film transistor. The gate line is connected to a gate of the thin-film transistor to control on or off of the thin-film transistor. The pixel electrode is connected to one of a source electrode and a drain electrode of the thin-film transistor. The data line is connected to the other of the source electrode and the drain electrode of the thin-film transistor. The data line inputs a voltage signal required the display image to the pixel electrode through the thin-film transistor to achieve the display of the arrayed substrate.

For example, the opposing substrate may be a color film substrate, and a color film layer corresponding to the pixel units and a black matrix covering the structures such as a gate line and a data line that are located in a non-display area may be provided on a side of the color film substrate facing toward the array substrate. For example, a common electrode disposed opposite the pixel electrode may also be provided on the side of the color film substrate facing toward the array substrate. The common electrode is configured to apply a common voltage to generate an electric field with the pixel electrode to drive liquid crystal molecules in the liquid crystal layer to deflect. The liquid crystal molecules are deflected to change the transmissivity of the liquid crystal layer, thereby realizing the display of a desired grayscale image. For example, both the common electrode and the pixel electrode may be located on the array substrate.

The following statements should be noted:
(1) The accompanying drawings related to the embodiment(s) of the present disclosure involve only the structure(s) in connection with the embodiment(s) of the present disclosure, and other structure(s) can be referred to common design(s).
(2) In case of no conflict, features in one embodiment or in different embodiments of the present disclosure can be combined.

The foregoing is merely exemplary embodiments of the disclosure, but is not used to limit the protection scope of the disclosure. The protection scope of the disclosure shall be defined by the attached claims.

1. A light-emitting substrate, comprising:
a substrate, comprising at least a first region and a second region, the first region comprising a center of the substrate, and the second region being located at an edge of the substrate; and
a plurality of light-emitting units, located on the substrate;
wherein the plurality of light-emitting units include at least a plurality of first light-emitting units and a plurality of second light-emitting units, the plurality of first light-emitting units are located in the first region, the plurality of second light-emitting units are located in the second region, a distance between at least two adjacent first light-emitting units is greater than a distance between at least two adjacent second light-emitting units, or a light intensity of a first light-emitting unit is less than a light intensity of a second light-emitting unit.

2. The light-emitting substrate according to claim 1, wherein a ratio of an illuminance at any point in the second region to an illuminance at any point in the first region is in a range from 0.6 to 1.

3. The light-emitting substrate according to claim 1, wherein the second region surrounds the first region, and a minimum distance between an edge of the second region close to the center of the substrate and an edge of a light-emitting region of the light-emitting substrate is not greater than 30 mm.

4. The light-emitting substrate according to claim 1, wherein an edge of the first region is in contact with an edge of the second region, the plurality of first light-emitting units in the first region are equally spaced, and at least some of the plurality of second light-emitting units in the second region are unequally spaced.

5. The light-emitting substrate according to claim 4, wherein the second region comprises at least a first sub-region and a second sub-region, the first sub-region is located between the second sub-region and the first region, and a distance between at least two adjacent second light-emitting units in the second sub-region is less than a distance between at least two adjacent second light-emitting units in the first sub-region.

6. The light-emitting substrate according to claim 5, wherein the first region is in a shape of a quadrangle, the quadrangle comprises a first side and a second side connected to each other, the plurality of light-emitting units are arranged in an array in a direction parallel to the first side and a direction parallel to the second side, and a distance between adjacent second light-emitting units is gradually decreases in a direction pointing from the center of the substrate to the edge of the substrate and parallel to at least one of the first side and the second side.

7. The light-emitting substrate according to claim 1, further comprising:
a plurality of light transmitting protection structures, which are disposed in a one-to-one correspondence with the plurality of light-emitting units and wrap a portion of the plurality of light-emitting units other than a portion in contact with the substrate,
wherein the light transmitting protection structure corresponding to the second light-emitting unit in at least a portion of the second region is provided with an inorganic light emitting material, and the at least a portion of the second region comprises a region that is farthest from the center of the substrate in the second region.

8. The light-emitting substrate according to claim 7, wherein the second region comprises at least a first sub-region and a second sub-region, the first sub-region is located between the second sub-region and the first region, and light transmitting protection structures corresponding to at least some second light-emitting units at least in the second region are provided with the inorganic light emitting material.

9. The light-emitting substrate according to claim 8, wherein a concentration of the inorganic light emitting material disposed in at least one light transmitting protection structure in the second sub-region is greater than a concentration of the inorganic light emitting material disposed in at least one light transmitting protection structure in the first sub-region.

10. The light-emitting substrate according to claim 7, further comprising:
a light conversion layer, located on a side of the plurality of light transmitting protection structures away from the substrate,
wherein the plurality of light-emitting units emit blue light, the light conversion layer is configured to convert the blue light emitted by the plurality of light-emitting units to white light, and the inorganic light emitting material is configured to convert the blue light emitted by the plurality of second light-emitting units to white light.

11. The light-emitting substrate according to claim 10, wherein the light conversion layer comprises at least one of a quantum dot material and a fluorescent material.

12. The light-emitting substrate according to claim 1, wherein a light intensity of at least one first light-emitting unit is less than a light intensity of at least one second light-emitting unit, the plurality of light-emitting units are arranged in an array, and the plurality of light-emitting units are equally spaced in at least one arrangement direction.

13. The light-emitting substrate according to claim 1, further comprising:
a reflection layer, located on a side of the substrate provided with the plurality of light-emitting units,
wherein the reflection layer comprises a plurality of openings, the plurality of openings are disposed in one-to-one correspondence with the plurality of light-emitting units.

14. The light-emitting substrate according to claim 7, wherein a material of the plurality of light transmitting protection structures comprises organic silica gel, and a refractive index of the plurality of light transmitting protection structures is in a range from 1.3 to 1.7 and a transmissivity of the plurality of light transmitting protection structures is greater than 80%.

15. The light-emitting substrate according to claim 1, wherein each light-emitting unit comprises an unpackaged light-emitting diode chip, and a maximum size of the unpackaged light-emitting diode chip in a direction parallel to the substrate is not greater than 500 μm.

16. A backlight source, comprising the light-emitting substrate according to claim 1.

17. A display device, comprising the light-emitting substrate according to claim 1.

18. The light-emitting substrate according to claim 2, wherein an edge of the first region is in contact with an edge of the second region, the plurality of first light-emitting units in the first region are equally spaced, and at least some of the plurality of second light-emitting units in the second region are unequally spaced.

19. The light-emitting substrate according to claim 3, wherein an edge of the first region is in contact with an edge of the second region, the plurality of first light-emitting units in the first region are equally spaced, and at least some of the plurality of second light-emitting units in the second region are unequally spaced.

20. The light-emitting substrate according to claim 2, further comprising:
a plurality of light transmitting protection structures, which are disposed in a one-to-one correspondence with the plurality of light-emitting units and wrap a portion of the plurality of light-emitting units other than a portion in contact with the substrate,
wherein the light transmitting protection structure corresponding to the second light-emitting unit in at least a portion of the second region is provided with an inorganic light emitting material, and the at least a portion of the second region comprises a region that is farthest from the center of the substrate in the second region.
